(19) United States
(12) Patent Application Publication
(10) Pub. No.: US 2008/0278905 A1
(43) Pub. Date: Nov. 13, 2008

(54) INFORMATION HANDLING SYSTEMS INCLUDING FAN CONTROL MODULES AND METHODS OF USING THE SYSTEMS

(75) Inventors: Paul T. Artman, Austin, TX (US); Stuart A. Berke, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: DELL PRODUCTS, LP, Round Rock, TX (US)

(21) Appl. No.: 11/746,143

(22) Filed: May 9, 2007

(51) Int. Cl. H05K 7/20

(52) U.S. Cl. 361/685; 361/687

(57) ABSTRACT

An information handling system can include a fan control module operable to be control a fan to cool components within a housing. The fan control module can include a communication module operable to receive configuration information associated with components disposed within a housing of an information handling system. The fan control module can also include a processor operable to determine a fan control signal using the configuration information. In particular embodiments, the fan control module can determine an idling speed that reflects the actual configuration of the information handling system.

### FIELD OF THE DISCLOSURE

This disclosure relates generally to information handling systems, and more particularly to information handling systems including fan control modules and methods of using the systems.

### DESCRIPTION OF THE RELATED ART

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

Power consumption and heat dissipation are becoming more challenging with newer designs of information handling systems. Many different components may be installed within a housing, and a fan or fans disposed within the housing is used to move air through the housing to help dissipate heat by convection. The fan speed of the fan(s) can be dynamically controlled using a conventional technique. The control can vary from an idling speed to a highest operating speed. The control may be based on the current usage of the processor(s) (e.g., 30% of maximum load), by thermal sensors embedded within the processor(s) or embedded within processor(s) and power supply(ies).

The idling speed for the fan can be determined at a factory by establishing the most thermally challenging scenario to which the information handling system would be exposed. Such a scenario may assume that the largest number of components are present and use the greatest amount of power. For example, if the information handling system has two sockets for two processors, and the maximum normal operating power for each processor can range from approximately 30 to 160 watts of power. In this example, the idling speed would be determined assuming that each socket has a processor capable of operating at 160 watts, even if only one processor having a maximum normal operating power of 70 watts power is actually used. In limited situations, the number of fans within an information handling system can be changed at a factory based on components actually used; however, the idling speed for the fan(s) is not affected.

### BRIEF DESCRIPTION OF THE DRAWINGS

Skilled artisans appreciate that elements in the figures are illustrated for simplicity and clarity and have not necessarily been drawn to scale. For example, the dimensions of some of the elements in the figures may be exaggerated or minimized relative to other elements to help to improve understanding of embodiments of the invention. Embodiments incorporating teachings of the present disclosure are illustrated and described with respect to the drawings presented herein.

FIG. 1 includes a functional block diagram of an information handling system including a basic input/output system and a main circuit board control module.

FIG. 2 includes a physical block diagram illustrating airflow and components within a housing of an information handling system.

FIG. 3 includes a functional block diagram of a basic input/output system module.

FIG. 4 includes a functional block diagram of a main circuit board control module.

FIGS. 5 and 6 include a flow diagram of a method of using configuration information to determine a fan speed for an information handling system.

FIG. 7 includes a table of processors and their corresponding thermal design points.

FIG. 8 includes a table of configuration information and fan speed offset (idling speed).

FIG. 9 includes plots of fan power using a method in accordance with an embodiment as compared to a conventional method.

The use of the same reference symbols in different figures indicates similar or identical items.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. The teachings can also be utilized in other applications and with several different types of architectures such as distributed computing architectures, client/server architectures, or middleware server architectures and associated components.

For purposes of this disclosure, an information handling system can include any instrumentality or aggregate of instrumentalities operable to compute, classify, process, transmit, receive, retrieve, originate, switch, store, display, manifest, detect, record, reproduce, handle, or use any form of information, intelligence, or data for business, scientific, control, entertainment, or other purposes. For example, an information handling system can be a personal computer, a PDA, a consumer electronic device, a network server or storage device, a switch router, wireless router, or other network communication device, or any other suitable device and can vary in size, shape, performance, functionality, and price. The information handling system can include memory (volatile (e.g. random access memory, etc.), nonvolatile (read only memory, flash memory etc.) or any combination thereof), one or more processing resources, such as a central processing unit (CPU), hardware or software control logic, or any combination thereof. Additional components of the information handling system can include one or more storage devices, one or more communications ports for communicating with external devices as well as various input and output (I/O) devices, such as a keyboard, a mouse, a video display, or any combination thereof. The information handling system can also include one or more buses operable to transmit communications between the various hardware components.

Although referred to as a “device,” the device may be configured as hardware, firmware, software, or any combination thereof. For example, the device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device). Similarly, the device could be firmware (such as any software running on an embedded device, a Pentium class or PowerPC™ brand processor, or other such device) or software (such as any software capable of operating in the relevant environment). The device could also be a combination of any of the foregoing examples of hardware, firmware, or software.

Devices or programs that are in communication with one another need not be in continuous communication with each other unless expressly specified otherwise. In addition, devices or programs that are in communication with one another may communicate directly or indirectly through one or more intermediaries.

Embodiments discussed below describe, in part, distributed computing solutions that manage all or part of a communicative interaction between network elements. In this context, a communicative interaction may be intending to send information, sending information, requesting information, receiving information, receiving a request for information, or any combination thereof. As such, a communicative interaction could be unidirectional, bidirectional, multi-directional, or any combination thereof. In some circumstances, a communicative interaction could be relatively complex and involve two or more network elements. For example, a communicative interaction may be “a conversation” or series of related communications between a client and a server—each network element sending and receiving information to and from the other. Whatever form the communicative interaction takes, the network elements involved need not take any specific form. A network element may be a node, a piece of hardware, software, firmware, middleware, some other component of a computing system, or any combination thereof.

In the description below, a flow charted technique may be described in a series of sequential actions. The sequence of the actions and the party performing the steps may be freely changed without departing from the scope of the teachings. Actions may be added, deleted, or altered in several ways. Similarly, the actions may be re-ordered or looped. Further, although processes, methods, algorithms or the like may be described in a sequential order, such processes, methods, algorithms, or any combination thereof may be operable to be performed in alternative orders. Further, some actions within a process, method, or algorithm may be performed simultaneously during at least a point in time (e.g., actions performed in parallel), can also be performed in whole, in part, or any combination thereof.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single device is described herein, more than one device may be used in place of a single device. Similarly, where more than one device is described herein, a single device may be substituted for that one device.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the computing, electronics, and software arts.

According to an aspect, a method of using an information handling system can include receiving configuration information of components disposed within a housing of the information handling system. The method can also include placing a fan at a first fan speed in response to receiving the configuration information, wherein the fan is operable to assist in moving a gas across the components.

According to another aspect, an information handling system can include a housing and components disposed within the housing, wherein collectively, the components are operable to handle information. The information handling system can also include a configuration module operable to generate configuration information based on the components disposed within the housing. The information handling system can also include a fan control module and a fan. The fan control module can be coupled to the configuration module, wherein the fan control module is operable to generate a fan control signal in response to the configuration information. The fan can be communicatively coupled to the fan control module and physically coupled to the housing, wherein the fan is operable to provide gas flow adjacent to the components in response to the fan control signal.

According to a further aspect, a fan control module can be operable to be control a fan to cool components within a housing. The fan control module can include a communication module and a processor. The communication module can be operable to receive configuration information associated with components disposed within a housing of an information handling system. The processor can be operable to determine a fan control signal using the configuration information.

An information handling system and method of using it are described below. An exemplary, non-limiting system description is described before addressing methods of using it. Some of the functionality of modules within the system is described with the system. The utility of the system and its modules will become more apparent with the description of the methods that follow the description of the system and modules.

FIG. 1 illustrates a functional block diagram of an exemplary embodiment of an information handling system, generally designated at 100. In one form, the information handling system 100 can be a computer system such as a server. Alternatively, the information handling system 100 can include a desktop computer, a laptop computer, another similar computer, a rack of computers (e.g., networked servers), or any combination thereof. Other implementations can be used. After reading this specification, skilled artisans will appreciate that the information handling system can be configured to their particular needs or desires.

As illustrated in FIG. 1, the information handling system 100 can include a first physical processor 102 coupled to a first host bus 104 and can further include additional processors generally designated as n^{th} physical processor 106 coupled to a second host bus 108. The first physical processor 102 can be coupled to a chipset 110 via the first host bus 104. Further, the n^{th} physical processor 106 can be coupled to the chipset 110 via the second host bus 108. The chipset 110 can support multiple processors and can allow for simultaneous processing of multiple processors and support the exchange of information within information handling system 100 during multiple processing operations.

According to one aspect, the chipset 110 can be referred to as a memory hub or a memory controller. For example, the chipset 110 can include an Accelerated Hub Architecture (AHA) that uses a dedicated bus to transfer data between first physical processor 102 and the n^{th} physical processor 106. For example, the chipset 110 including an AHA enabled-chipset can include a memory controller hub and an input/output (I/O) controller hub. As a memory controller hub, the chipset 110 can function to provide access to first physical processor 102 using first bus 104 and n^{th} physical processor 106 using the second host bus 108. The chipset 110 can also provide a memory interface for accessing memory 112 using a third host bus 114. In a particular embodiment, the host buses 104, 108, and 114 can be individual buses or part of the same bus. The chipset 110 can also provide bus control and can handle transfers between the host buses 104, 108, and 114.

According to another aspect, the chipset 110 can be generally considered an application specific chipset that provides connectivity to various buses, and integrates other system functions. For example, the chipset 110 can be provided using an Intel®-brand Hub Architecture (IHA) chipset also that can include two parts, a Graphics and AGP Memory Controller Hub (GMCH) and an I/O Controller Hub (ICH). For example, an Intel 820E, an 815E chipset, or any combination thereof, available from the Intel Corporation of Santa Clara, Calif., can provide at least a portion of the chipset 110. The chipset 110 can also be packaged as an application specific integrated circuit (ASIC).

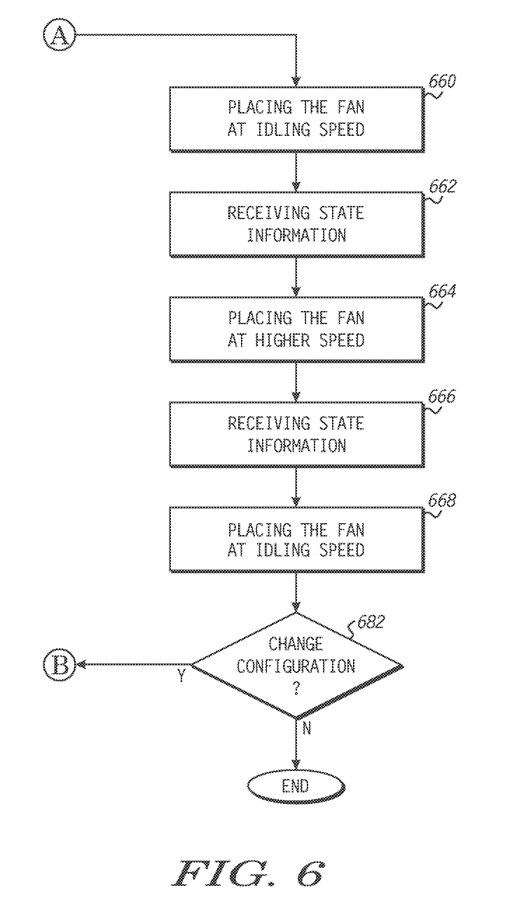

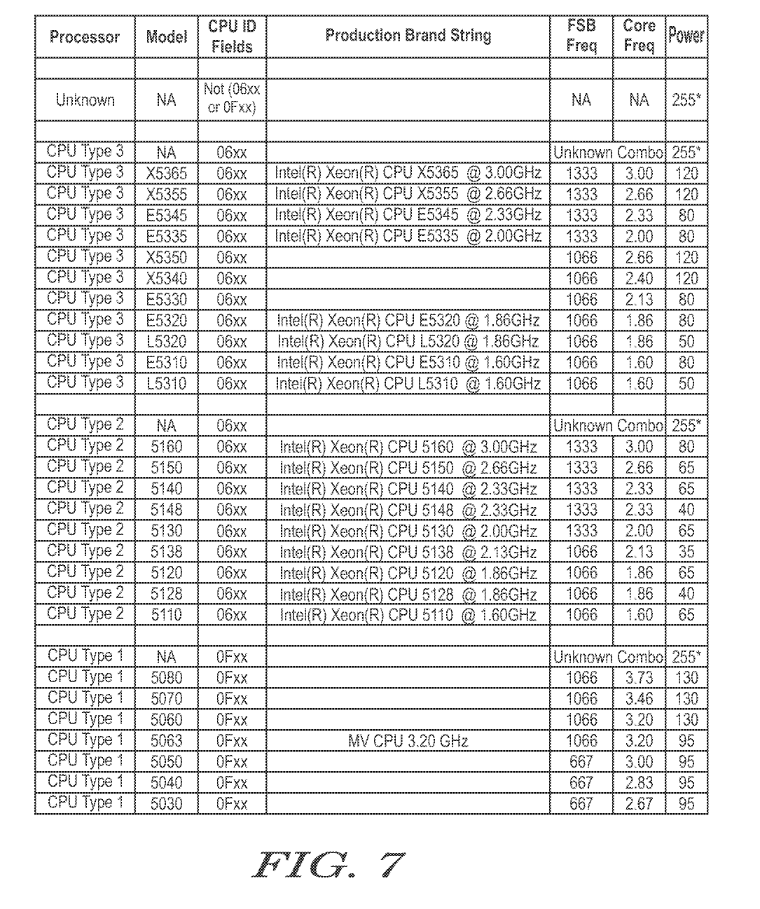

In the description below, a physical description of hardware, firmware, or software embodiments is described with respect to FIGS. 1 to 4. Much of the physical description will include couplings, connections, and some functionality description. A method description is described with respect to FIGS. 5 and 6, with references to the components of described in FIGS. 1 to 4.

The information handling system 100 can also include a video graphics interface 122 that can be coupled to the chipset 110 using fourth host bus 124. In one form, the video graphics interface 122 can be an Accelerated Graphics Port (AGP) interface to display content within a video display unit 126. Other graphics interfaces may also be used. The video graphics interface 122 can provide a video display output 128 to the video display unit 126. The video display unit 126 can include one or more types of video displays such as a flat panel display (FPD) or other type of display device.

The information handling system 100 can also include an I/O interface 130 that can be connected via an I/O bus 120 to the chipset 110. The I/O bus 120 and the I/O interface 130 can include industry standard buses or proprietary buses and respective interfaces or controllers. The I/O bus 120 can also include a Peripheral Component Interconnect (PCI) bus or a high speed PCI-Express bus. In one embodiment, a PCI bus can be operated at approximately 66 Mhz and a PCI-Express bus can be operated at approximately 128 Mhz. PCI buses and PCI-Express buses can be provided to comply with industry standards for connecting and communicating between various PCI-enabled hardware devices. Other buses can also be provided in association with, or independent of, the I/O host bus 120 including other industry standard buses or proprietary buses, such as Industry Standard Architecture (ISA), Small Computer Serial Interface (SCSI), Inter-Integrated Circuit (I²C), System Packet Interface (SPI), or Universal Serial buses (USBs).

In an alternate embodiment, the chipset 110 can be a chipset employing a Northbridge/Southbridge chipset configuration (not illustrated). For example, a Northbridge portion of the chipset 110 can communicate with the first physical processor 102 and can control interaction with the memory 112, the fourth bus 120 operable as a PCI bus, and activities for the video graphics interface 122. The Northbridge portion can also communicate with the first physical processor 102 using first bus 104 and the second bus 108 coupled to the n^{th} physical processor 106. The chipset 110 can also include a Southbridge portion (not illustrated) of the chipset 110 and can handle I/O functions of the chipset 110. The Southbridge portion can manage the basic forms of I/O such as USB, serial I/O, audio outputs, Integrated Drive Electronics (IDE), and ISA I/O for the information handling system 100.

The information handling system 100 can further include a disk controller 132 coupled to the fourth bus 120. The disk controller 132 can be used to connect one or more disk drives such as a hard disk drive (HDD) 134 and an optical disk drive (ODD) 136 such as a Read/Write Compact Disk (R/W-CD), a Read/Write Digital Video Disk (R/W-DVD), a Read/Write mini Digital Video Disk (R/W mini-DVD), or other type of optical disk drive.

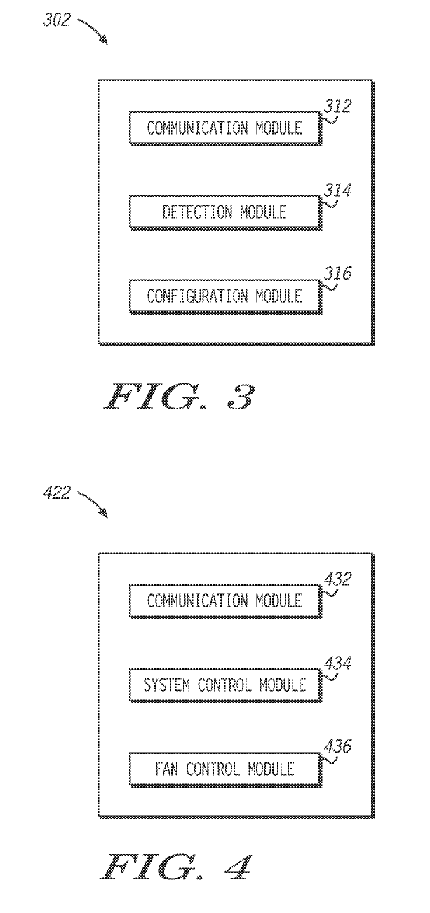

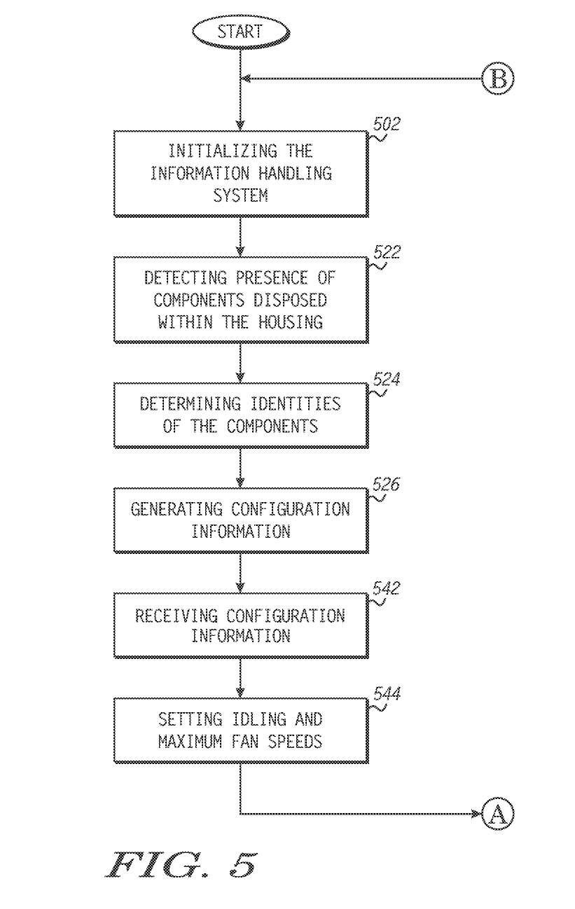

The information handling system 100 can also include basic input/output system (BIOS) module 140 that can be coupled to the I/O bus 120. The BIOS module 140 is operable to detect and identify components within the information handling system 100 and to provide the appropriate drivers for those components. The BIOS module 140 can be in the form of hardware, software, firmware, or any combination thereof. The BIOS module 160 may be a standalone integrated circuit or chip set or can be shared within other functions within an integrated circuit or chip set. Other functions and operations of modules within the BIOS module 160 are described with respect to FIG. 3.

The information handling system 100 can further include main circuit board control module 150 that can be coupled to the chipset 110 via a system communication bus 152, such as a control bus. The main circuit board control module 150 may reside on a main circuit board, such as a baseboard, a motherboard, or the like. Although not illustrated, other components, such as the processors (1st processor 102 through the n^{th} processor 106), the video display unit 126, the video graphic interface 122, the memory 112, and the disk controller 132 can be coupled to the main circuit board control module 150. Commands, communications, or other signals may be sent to or received from the main circuit board control module 150 by any one or combination of components previously described. The main circuit board control module 150 of an integrated circuit or a chip set within the information handling system 100. The main circuit board control module 150 can also be coupled to a fan 154 via a fan interface 156. In one embodiment, the fan 154 is a single fan, and in another embodiment is a set of fans. The system bus 152 and fan interface 156 can be an I²C bus, a System Manager (SM) bus, another suitable communication medium, or any combination thereof.

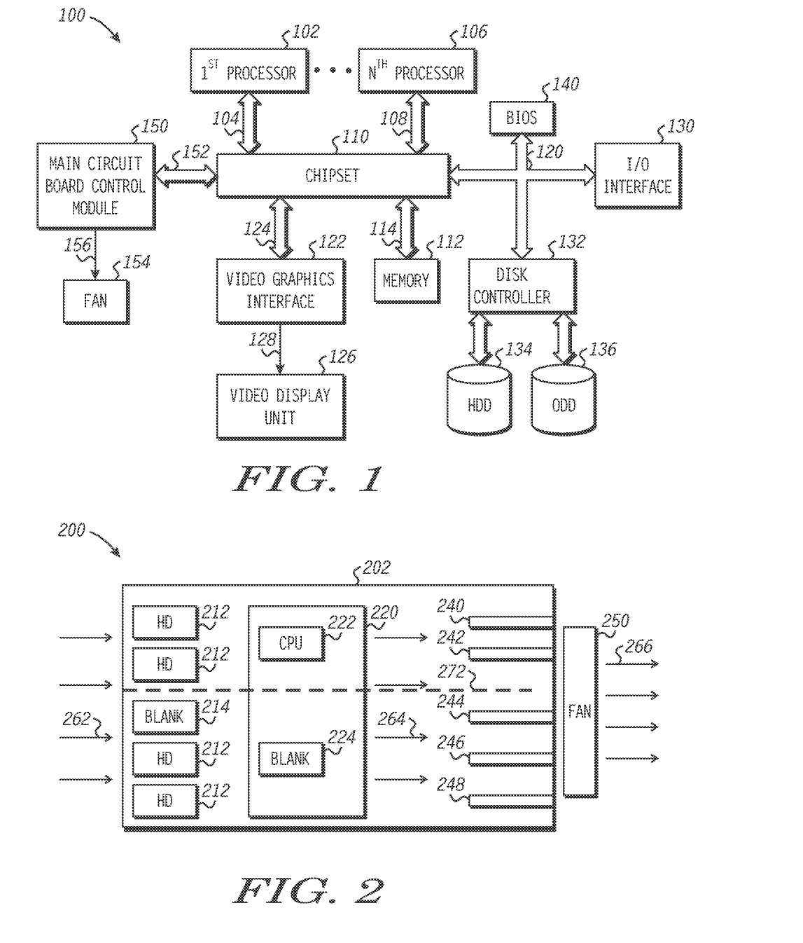

FIG. 2 includes a block diagram of a physical layout of an information handling system 200. As illustrated, the information handling system 200 includes a housing 202 and a variety of components disposed within the housing 202. The information handling system 200 can include a main circuit board 220 with two sockets for processors. In the particular embodiment illustrated, one socket has a processor, such as a central processing unit (CPU) 222, and the other socket is blank 224 (i.e., does not have a processor). Regarding blank 224, the socket can be unoccupied or occupied with a form having no substantial electrical function and a shape similar to CPU 222.

The information handling system 200 includes a plurality of disk drive slots. In a particular embodiment, HDDs 212 are within all of the slots, except for one, which has a blank 214. The blank 214 has a shape and other external characteristics that are similar to the HDDs 212. In this manner, gas flowing through the information handling system 200 remains substantially the same regardless of the number of HDDs within the disk drive slots. In other embodiments, a digital video disk (DVD) or compact disk (CD) drive may be used in conjunction with or in place of an HDD 212.

The information handling system 200 further includes cards 240, 242, 244, 246, and 248. The cards can include a memory module, a network interface card, a personal computer card, a video card, another suitable card, more than one of any of the foregoing cards, or any combination thereof. In another embodiment, a position for a card may be left unoccupied or include a blank card (e.g., has no substantial electrical function and a form similar to another card). Other components can be included within the housing but are not illustrated. In one embodiment, an optional partition (illustrated by dashed line 272) can be used to divide the housing into different parts. The partition may be substantially strait or include corners, bends, or other features. If needed or desired, more than one partition can be used in the housing 200.

The information handling system 200 further includes a fan 250 fluidly coupled to the housing 202. The fan 250 is a single fan or a set of fans. The fan 250 is disposed within the housing 202, located downstream from the housing 202, located upstream of the housing 202, or any combination thereof. If the fan 250 is located outside the housing 202, the fan 250 can be attached to the housing or positioned such that gas is pushed by the fan 250 towards the housing 202 or gas is pulled by the fan 250 from the housing 202. Thus, the term “fluidly coupled” should be construed broadly.

In the embodiment illustrated in FIG. 2, the fan 250 pulls gas, such as air, nitrogen, argon, or the like towards the housing (illustrated by arrows 262). Before entering the housing 202, the gas has an inlet temperature in a range of approximately 20 to 25° C. in a particular embodiment. The gas is flows through the housing in a direction illustrated by arrows 264. The gas flows across the HDDs 212 and blank 214, then across the main circuit board 220 (including the CPU 222 and the blank 224), and then across the cards 240, 242, 244, 246, and 248 before leaving the housing 202. The effluent temperature of the gas after leaving the housing 202 can be in a range of approximately 5 to approximately 25° C. higher than the inlet temperature. The effluent temperature varies based on the type and number of components, and how hard the components are driven. The gas is propelled by the fan 250, which is illustrated by arrows 266.

Each of the components within the housing may be characterized by a maximum amount of power that is provided or is consumed during normal operation of the particular component. Alternatively, the characterization may be a “not to exceed” power consumption or a Thermal Design Point (TDP). As used in this specification, the term “maximum power rating” will be used to refer to any of the foregoing characterizations.

Each processor that can be inserted into a socket may have a maximum power rating in a range of approximately 30 watts to approximately 160 watts. HDDs 212 vary based on drive type and speed. For example, a SATA 7200 revolutions/minute (rpm) drive can have a maximum power rating of approximately 10 watts of power, a SATA 10,000 rpm drive can have a maximum power rating of approximately 15 watts of power, a SAS 10,000 rpm drive can have a maximum power rating of approximately 20 watts of power, and a SAS 15,000 rpm drive can have a maximum power rating of approximately 25 watts of power. Each of the cards 240, 242, 244, 246, and 248 can have a maximum power rating of approximately 20 watts. In other embodiments, the maximum power ratings may be lower or higher the values described above.

FIGS. 3 and 4 include block diagrams of modules that can be included with the BIOS module 302 and main circuit board control module 422. The BIOS module 302 includes a communications module 312, a detection module 314, and a configuration module 316. The communications module 312 is operable to allow the BIOS module 302 to send and receive communications from other parts of the information handling system.

The detection module 314 is operable to determine if a disk drive, a processor, a card, or other component is present. For example, if the detection module 314 can communicate with a component at a particular location (e.g., a socket or slot), then the detection module 314 determines that the particular location is occupied by the component. If the detection module 314 cannot establish communication at a particular location, the detection module 314 determines that the particular location is unoccupied or has a blank and will not significantly contribute to power consumption.

Information collected by the detection module 314 can be sent to and received by the configuration module 316. The configuration module 316 is operable to determine the type of component at each location. For example, the configuration module 314 can determine whether a particular component is disk drive, a processor, a card, and more particularly, the classification of the particular component (e.g., SAS 7200 rpm drive, Intel Xeon™-brand processor @ 2.33 GHz, a 4 GB dual in-line memory module (DIMM) with DRAMs having ×4 data organization, etc.). The configuration information can be at any level of granularity, as needed or desired. In an alternative embodiment, the components can be further broken down by manufacturer, model number, serial number, or the like. After reading this specification, skilled artisans will be able to determine the level of detail regarding the configuration information. The configuration information may include maximum power ratings for each of the components. Such information can be provided by the original equipment manufacturer (OEM). The information from the OEM can be used as is or can be scaled or offset as needed or desired.

The main circuit board control module 422 includes a communications module 432, a system control module 434, and a fan control module 436. The communications module 432 is operable to allow the main circuit board control module 302 to send and receive communications from other parts of the information handling system. The system control module 434 is operable to perform conventional or proprietary functions during operation of the information handling system.

The fan module 436 is operable to receive configuration information from the BIOS module 302 via the communication module 432. Maximum power ratings for the components can be included with the configuration information or can be determined from tables or other information. The fan control module 436 is operable to set the idling speed, maximum normal operating speed, or both using the configuration information. Note that the configuration information include information on the actual configuration, which can be substantially from a configuration representing a worst-case scenario from a thermal dissipation perspective

The fan control module 436 is operable to control the speed of the fan based on real time or near real time state information. As used herein, real time refers to changes that occur substantially at the same time after receiving information regarding a changed state, and near real time refers to changes that occur no more than approximately 10 second after receiving information regarding a changed state. More particularly, the fan control module 434 can also receive information regarding a load on a processor, a reading on thermal sensor within a processor, power supply, or any combination thereof. The fan control module 436 can dynamically change a fan speed based on a change in state information. The fan control module 436 is operable to generate a fan control signal that is sent by the communication module 432 to the fan.

The BIOS module 302 and the main circuit board control module 422 have been described with respect to modules therein. In other embodiment, more, fewer, or different modules may be used. Further, the functions of one module may be combined with functions of another module or may be split between different modules. For example, within the BIOS module 302, the main circuit board control module 422, or both, the communication module could include one communication module operable to transmit signals and another communication module to receive signals. More than one communication module may be used for different buses or interfaces. For example, the communication module 432 within the main circuit board control 422 may include one communication module operable to communicate with the fan, and another communication module to communicate with other components within the information handling system. All or part of the functions described with respect to the configuration module 316 of the BIOS module 302 may be moved to the main circuit board control module 422. The modules can include logic that is in hardware, firmware, software, or any combination thereof. After reading this specification, skilled artisans will appreciate that the design of the information handling system, including the BIOS module and main circuit board control module are flexible and can be modified from the embodiments described herein to meet their needs or desires.

FIGS. 5 and 6 include a flow diagram of a method of using an information handling system having a fan control sub-system. The method can be employed in whole or in part by the information handling system 200 depicted in FIG. 2, the information handling system 100 depicted in FIG. 1, or any other type of information handling operable to use the method, as illustrated in FIGS. 5 and 6. Additionally, the method can be embodied in various types of encoded logic including software, firmware, hardware, or other forms of digital storage mediums or logic, or any combination thereof, operable to provide all or portions of the method of FIGS. 5 and 6. While much of the method as illustrated in FIGS. 5 and 6 is described with respect to FIGS. 1 to 4, after reading this specification, skilled artisans will appreciate that many other configurations may be used. Thus, the figures are to aid in the understanding of particular embodiments, and do not limit the scope of the present invention.

The method can include initializing the information handling system, at block 502 in FIG. 5. Initialization can include applying power to a system, booting a system, rebooting a system, reinitializing a system, or any other type of process that may institute initializing an information handling system. The method can also include detecting the presence of components disposed within the housing, at block 522, determining identities of the components, at block 524, and generating configuration information, at block 526. These activities may be performed as part of or separately from the initialization in block 502. In one embodiment, the detection module 314 and configuration module 316 within the BIOS module 302 performs these functions. Regarding identities of components, the identities can include relatively high-level information (e.g., disk drive, memory card, video card, processor, fan etc.), or other information (e.g., SAS 7200 rpm disk drive, 4 GB DIMM with DRAMs having ×4 data organization, Xeon™-class microprocessor, 75 cubic feet/minute (CFM) fan, etc.). If needed or desired, the information can be more specific and include OEM name (e.g., Samsung, Hitachi, Intel, etc.), model number, serial number, maximum normal operating maximum power rating, other suitable information, or any combination thereof.

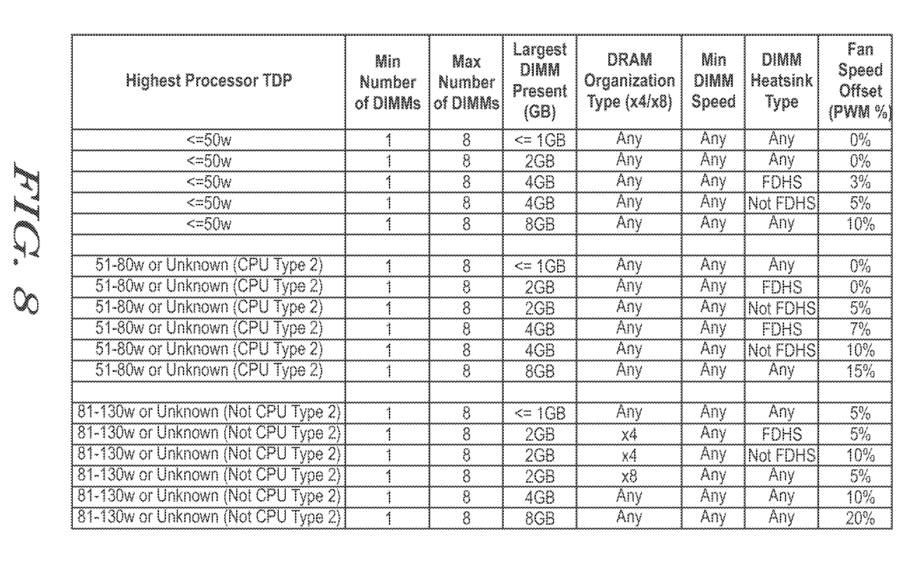

In one particular embodiment, the maximum power rating can be obtained from a table that is internal or external to the information handling system. For example, a maximum power rating table for processors can reside within the BIOS module 302, memory 112, HDD 134, ODD 136, or the like. Alternatively, the maximum power rating table for the processors can be obtained from a database within a storage network. FIG. 7 includes an example of the information. The detection module 314 can determine the processor name, model, CPU ID field, production brand string, front-side bus (FSB) frequency, core frequency, or any combination thereof. Using some or all of the information, the maximum power rating can be obtained from the table. If the processor cannot be identified or only partially identified, the highest maximum power rating will be assumed. For example, a main circuit board may have two sockets, but the processors are unknown. In this example, the main circuit board will be assumed to have two processors, and the maximum power rating will be 255 watts.

The configuration information can be sent from the BIOS module and received by the communication module, at block 542 of FIG. 5. More particularly, the configuration information can be forwarded from the configuration module 316 to the communication module 312 in FIG. 3, sent from the communication module 312 of the BIOS module 302 and received by the communication module 432 of the main circuit board control module 422, and forwarded to the system control module 434 and the fan control module 436.

The method can further include setting idling and maximum fan speeds, at block 544 in FIG. 5. Referring to FIG. 4, the fan control module 436 can set the fan speeds. The maximum fan speed can be determined by using the fan-related information within the configuration information. In one embodiment, the configuration information can include one fan with a fan identifier or a plurality of fans with different identifiers. The configuration information can include performance information regarding the fan (power consumption, gas flow, fan speed, pressure increase across the fan, other suitable information, or any combination thereof). If the performance information is not within the configuration information, it may be obtained from a data table, the fan OEM, or other source. The maximum setting can correspond to the maximum operating gas flow, fan speed, power, or any combination thereof of the fan(s) within the information handling system.

The configuration information can be used to set the idling fan speed. The idling fan speed corresponds to the fan speed used when the information handling system is idling or operating with no component or system thermal sensors indicating a fan speed up is required. By using the configuration information, the idling speed can be set significantly lower than would otherwise occur using a conventional method. For example, the main circuit board may have two sockets for processors that could have a combined maximum power rating of 260 watts. The actual main circuit board within the information handling system may have only one processor with a maximum power rating of 80 watts. Thus, when idling, the information handling system may consume approximately 40 watts of power, as opposed to approximately 130 watts that could occur if two processors with a combined maximum power rating of 260 watts would be present.

Additionally, the configuration information can include the number and type of disk drives and cards within the information handling system. Disk drives and cards consume power and generate heat, and such power consumption and heat generation may not be accounted for in a conventional method. Currently, disk drives and cards do not include thermal sensors; however OEMs typically provide maximum power ratings. This information may be used directly, or a derivative of the information can be used. For example, the idling power of a disk drive may be 25% of the maximum power, and the idling power of an interface card may be 50% of the maximum power. These numbers are merely used for illustrative purposes, and actual numbers used can vary.

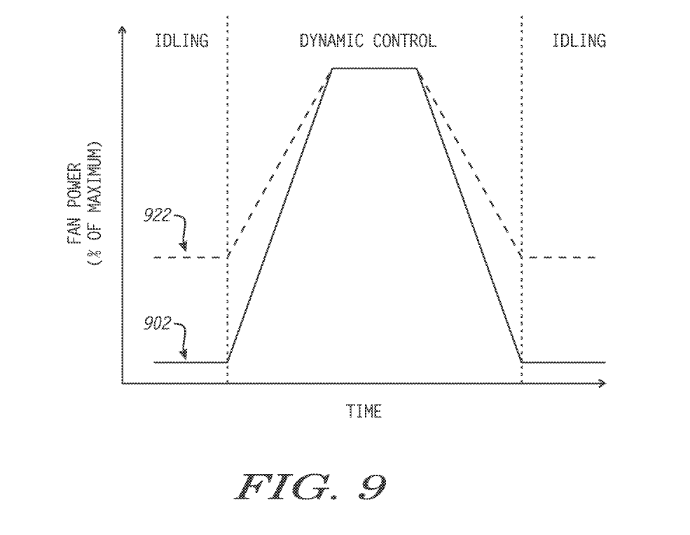

A data table, an equation, or the like can be used to determine the idling fan speed based on the configuration information. In one embodiment, a data table can be used. Referring to FIG. 8, the highest processor TDP (a specific type of maximum power rating), minimum number of DIMMs, maximum number of DIMMs, largest DIMM present, DRAM organization, minimum DIMM speed, DIMM heatsink type, other suitable information, or any combination thereof can be used as an input to find an entry corresponding to the idling speed, which can be the fan speed offset. In another embodiment, disk drive or other card information can be used in conjunction with or in place of the DIMM information. More information or less information can be used. In another embodiment, values can be extracted from the configuration information and input into an equation to determine the idling speed.

Compare the previously described method with a conventional method. In a conventional method, the most thermally challenging scenario for the information handling system would be used as a basis for setting the idle speed of the fan. For example, if the main circuit board includes two sockets for processors, both sockets would be assumed to be occupied by the processors consuming the greatest amount of power. The power consumption when the processors are idling can be approximately 130 watts. Note that this can be significantly higher than an actual configuration that may consume only approximately 40 watts of power.

In one particular conventional method, the idling fan speed may be determined using only the main circuit board/processor information for the potentially worst-case thermal scenario. This information would assume all processor sockets would be occupied by processing having the highest possible maximum power ratings. Thus, if the main circuit board would have two processor slots, both would assumed to be occupied, and the if each processor would have a maximum power rating in a range of 30 to 130 watts, each processor would assumed to have a maximum power rating of 130 watts. Note that these assumptions can result in a theoretical configuration that is substantially different from the actual configuration, which may have only one processor with a maximum power rating of 80 watts.

In another conventional method, other components could be also considered with the main circuit board/processor information of the worst-case scenario. All disk drive positions would be assumed to be occupied and have the highest power consuming disk drive that could be used in the disk drive slots. Similar to the processor sockets, not all of the disk drive slots may be occupied by a disk drive in the actual configuration, and if occupied, the actual disk drive may consume substantially less power than a disk drive having the highest maximum power rating. Thus, idling fan speed determined by the conventional method is significantly higher than an embodiment of the present invention because the conventional method considered a worst-case scenario, whereas a method in accordance with the present invention considers the actual configuration and sets the idling fan speed at a level that more accurately reflects that information handling system as actually configured.

After all the actions in FIG. 5 have been performed and other initial activity has been completed, the information handling system can be in an idle state. The method can continue with placing the fan at idling speed, at block 660 in FIG. 6. The fan control module 436 in FIG. 4 can send a fan control signal to the fan 154 in FIG. 1, wherein the fan control signal includes the idling speed information. The improvement by using an embodiment described herein is illustrated in FIG. 9, which includes plots of power needed to operate the fans using an embodiment described herein (solid line 902) as compared to a conventional method (dashed line 922). Clearly, the idling speed for the fan is significantly lower for the method using configuration information, as opposed to the conventional method. In a particular embodiment, the power consumed by the fan may be 26 watts when actual configuration information is used, and 58 watts using the conventional method. Power savings will vary for other information handling systems that have different configurations. Still, when the information handling system is idling, the power reduction for the fan is significant.

At a later time, the information handling system can become active. State information can be generated that reflects the activity. The method can also include receiving state information, at block 662 in FIG. 6. The state information can be generated by the system control module 434, another portion of the information handling system, or any combination thereof and be received by the fan control module 436 in FIG. 4. The method can further include placing the fan at higher speed, at block 664 in FIG. 6. Another fan control signal can be sent by the fan control module 436 and received by the fan 154. Referring to FIG. 9, the fan control can be a conventional or proprietary dynamic control process. In another embodiment, a different control process can be used. The power used by the fan may be substantially constant over time (as illustrated in FIG. 9) or vary over time (not illustrated in FIG. 9).

After a period of inactivity, the state information generated corresponds to an idling state. The method can also include receiving state information, at block 666, and placing the fan at the idling speed, at block 668 in FIG. 6. The state information can be received by the fan control module 436 in FIG. 4, and still another fan control signal can be sent by the fan control module 436 and received by the fan 154. Referring to FIG. 9, the fan returns to the idling speed. Again, the power savings is readily apparent.

Components within the housing can be added, removed, or replaced and potentially result in a different configuration. A determination can be made whether the configuration has changed, at decision tree 682. If the configuration has changed, the method returns to block 502 in FIG. 5, wherein the information handling system is initialized. Otherwise, the configuration may not be changed, and the system can be powered down. If more activity would occur before powering down the information handling system, the process can return to block 662.

By using the actual configuration information of the information handling system, the power consumer by the fan, particularly when idling, can be substantially reduced. The fan may idle at a lower fan speed because a worst-case configuration from a thermal dissipation perspective is not used to determine the idling speed. Power consumed by the fan can be reduced by over 50%, which is significant to all information handling systems, and particularly to portable, battery powered systems. Additional, the lower idling speed can result in less gas, such as air, flowing through the information handling system. The air savings can be particularly significant when many information handling systems are in close proximity (e.g., servers within a server rack). Utility and other costs associated with the gas (e.g., air conditioning, regulating humidity, filters, etc.) are also reduced due to the lower gas flow.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a method of using an information handling system can include receiving configuration information of components disposed within a housing of the information handling system. The method can also include placing a fan at a first fan speed in response to receiving the configuration information, wherein the fan is operable to assist in moving a gas across the components.

In one embodiment of the first aspect, placing the fan at the first fan speed includes placing the fan at an idling speed. In a particular embodiment, the method further includes receiving activity information for a first component, wherein the components include the first component, and placing the fan at a second fan speed, wherein the second fan speed is higher than the first fan speed. In a more particular embodiment, the method further includes determining the information handling system is in an idling state after placing the fan at the second fan speed, and placing the fan at the first fan speed after placing the fan at the second fan speed. In still a more particular embodiment, placing the fan at a second fan speed, placing the fan at the first fan speed after placing the fan at the second fan speed, or both are performed in real time or near real time.

In another embodiment of the first aspect, the method further includes determining identities of the components disposed within the housing. In a particular embodiment, determining the identities of the components includes determining types of the components. In a more particular embodiment, determining the identities of the components includes determining manufacturers of the components. In another more particular embodiment, determining the identities of the components includes determining model numbers of the components. In still another particular embodiment, the method further includes determining a number of components within each type of component.

In a second aspect, an information handling system can include a housing and components disposed within the housing, wherein collectively, the components are operable to handle information. The information handling system can also include a configuration module operable to generate configuration information based on the components disposed within the housing. The information handling system can also include a fan control module and a fan. The fan control module can be coupled to the configuration module, wherein the fan control module is operable to generate a fan control signal in response to the configuration information. The fan can be communicatively coupled to the fan control module and physically coupled to the housing, wherein the fan is operable to provide gas flow adjacent to the components in response to the fan control signal.

In one embodiment of the second aspect, the configuration module is part of a basic input/output system. In another embodiment, the fan control module is part of a main circuit board control module. In a particular embodiment, the fan control module is operable to receive information from configuration module and to access power characterization information associated with the components. In still another embodiment, the components include a disk drive, a memory module, a graphics card, an interface card, or the like.

In a further embodiment of the second aspect, the housing includes a partition between sections of the housing. In still a further embodiment, the fan is disposed within the housing. In yet a further embodiment, the fan is disposed outside the housing.

In a third aspect, a fan control module can be operable to be control a fan to cool components within a housing. The fan control module can include a communication module and a processor. The communication module can be operable to receive configuration information associated with components disposed within a housing of an information handling system. The processor can be operable to determine a fan control signal using the configuration information.

In one embodiment of the third aspect, the processor is operable to obtain maximum power ratings associated with the components.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Many other embodiments may be apparent to those of skill in the art upon reviewing the disclosure. Other embodiments may be used and derived from the disclosure, such that a structural substitution, logical substitution, or another change may be made without departing from the scope of the disclosure. Accordingly, the disclosure is to be regarded as illustrative rather than restrictive.

Certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of using an information handling system comprising:
receiving configuration information of components disposed within a housing of the information handling system; and
placing a fan at a first fan speed in response to receiving the configuration information, wherein the fan is operable to assist in moving a gas across the components.

2. The method of claim 1, wherein placing the fan at the first fan speed comprises placing the fan at an idling speed.

3. The method of claim 2, further comprising:
receiving activity information for a first component, wherein the components include the first component; and
placing the fan at a second fan speed, wherein the second fan speed is higher than the first fan speed.

4. The method of claim 3, further comprising:
determining the information handling system is in an idling state after placing the fan at the second fan speed; and
placing the fan at the first fan speed after placing the fan at the second fan speed.

5. The method of claim 4, wherein placing the fan at a second fan speed, placing the fan at the first fan speed after placing the fan at the second fan speed, or both are performed in real time or near real time.

6. The method of claim 1, further comprising determining identities of the components disposed within the housing.

7. The method of claim 6, wherein determining the identities of the components comprises determining types of the components.

8. The method of claim 7, wherein determining the identities of the components comprises determining manufacturers of the components.

9. The method of claim 7, wherein determining the identities of the components comprises determining model numbers of the components.

10. The method of claim 6, further comprising determining a number of components within each type of component.

11. An information handling system comprising:
a housing;
components disposed within the housing, wherein collectively, the components are operable to handle information;
a configuration module operable to generate configuration information based on the components disposed within the housing;
a fan control module coupled to the configuration module, wherein the fan control module is operable to generate a fan control signal in response to the configuration information; and
a fan communicatively coupled to the fan control module and physically coupled to the housing, wherein the fan is operable to provide gas flow adjacent to the components in response to the fan control signal.

12. The information handling system of claim 11, wherein the configuration module is part of a basic input/output system.

13. The information handling system of claim 11, wherein the fan control module is part of a main circuit board control module.

14. The information handling system of claim 13, wherein the fan control module is operable to receive information from configuration module and to access power characterization information associated with the components.

15. The information handling system of claim 11, wherein the components include a disk drive, a memory module, a graphics card, an interface card, or the like.

16. The information handling system of claim 11, wherein the housing includes a partition between sections of the housing.

17. The information handling system of claim 11, wherein the fan is disposed within the housing.

18. The information handling system of claim 11, wherein the fan is disposed outside the housing.

19. A fan control module operable to be control a fan to cool components within a housing, the fan control module comprising:
a communication module operable to receive configuration information associated with components disposed within a housing of an information handling system; and
a processor operable to determine a fan control signal using the configuration information.

20. The fan control module of claim 19, wherein the processor is operable to obtain maximum power ratings associated with the components.
